(19) United States
(12) Patent Application Publication
(10) Pub. No.: US 2026/0163076 A1
(43) Pub. Date: Jun. 11, 2026

(54) LITHIUM METAL ANODE COMPRISING PROTECTIVE LAYER

(71) Applicant: Belenos Clean Power Holding AG, Biel/Bienne (CH)

(72) Inventors: José-Antonio GONZALEZ, Lausanne (CH); Mario EL KAZZI, Zürich (CH); Tian LIU, Dietikon (CH); Ales STEFANCIC, Möhlin (CH); Marco CARBONI, Rome (IT)

(73) Assignee: Belenos Clean Power Holding AG, Biel/Bienne (CH)

(21) Appl. No.: 19/127,238

(22) PCT Filed: Dec. 21, 2023
(86) PCT No.: PCT/EP2023/087458

§ 371 Date: May 5, 2025

Related U.S. Application Data
(60) Provisional application No. 63/435,038, filed on Dec. 23, 2022.

(51) Int. Cl. H01M 10/42; C23C 14/34; H01M 4/02; H01M 4/04; H01M 4/134; H01M 4/1395; H01M 4/38; H01M 10/0525

(52) U.S. Cl. CPC H01M 10/4235; C23C 14/3407; H01M 4/0426; H01M 4/134; H01M 4/1395; H01M 4/382; H01M 10/0525; H01M 2004/021; H01M 2004/027

(57) ABSTRACT

A lithium metal anode (1, 10, 11, 12, 13, 14) for a battery, including an anode active substrate (2) including lithium metal, and a first lithium metal anode protective layer (3) provided on a surface (4) of the anode active substrate (2), the anode further including one or more of Li₂CO₃, Li₂O and LiOH, wherein the first lithium metal anode protective layer (3) includes a first halide of lithium. Also, a battery including the lithium metal anode, and a method of producing the lithium metal anode.

### TECHNICAL FIELD OF THE INVENTION

The present invention relates a lithium metal anode for a lithium-ion battery, the anode comprising a protective surface layer. The invention further relates to batteries comprising such a lithium metal anode and to methods of producing them.

### BACKGROUND

Rechargeable batteries have achieved remarkable success and commercialization in the past decades, as the most popular and reliable power sources for portable devices, electrical vehicles and energy storage stations. In particular, Li ion batteries triumph over other battery systems on the market owing to their high energy density and outstanding cycle stability.

Lithium metal comprising anodes are well-known anodes for lithium-ion batteries because of the high theoretical capacity (3860 mAh/g) of lithium. However, the high (electro-) chemical reactivity and strong tendency to form lithium dendrites at high current density and areal capacity hinder its wide applications. Dendrites will grow on the anode's surface, and pose a safety risk by potentially causing short circuits and battery failure. Furthermore, the reactivity between the metallic lithium and the electrolyte forms inactive Li so-called “dead Li” leading to the rapid fading of the cell.

Dendrites and dead lithium (i.e. lithium that has become inactive and does no longer take part in the electrochemical cycling) result from uneven lithium plating and stripping during charging and discharging cycles, which can be caused by a variety of reasons, such as mechanical stress, surface energy, structural defects, (electro-) chemical reactions. To reduce the risk of dendrite formation and dead lithium accumulation, and to increase the safety and lifetime of the batteries, several solutions have been investigated, including but not limited to the introduction of solid-state electrolytes, an artificial lithium metal host, adding additives to the electrolyte, and organic/inorganic passivation layers for liquid electrolyte-based batteries.

In particular lithium-ion conductive passivation layers, i.e. protective layers, such as artificial solid electrolyte interphase (SEI) coatings, have gained much interest. Although a natural SEI typically forms on the anode, it has proven to often be insufficient to prevent dendrite growth. Artificial SEI (a-SEI) layers act as barriers, inhibiting dendrite growth and providing a more stable surface for lithium deposition.

US2018/0294476 discloses a lithium secondary battery comprising as anode a foil or a coating of lithium or lithium alloy on a current collector, and a 1 nm-10 μm thin layer of a high-elasticity ultrahigh molecular weight (UHMW) polymer having a lithium ion conductivity of at least 10⁻⁶ S/cm and a molecular weight between 0.5*10⁶ and 9*10⁶ g/mole.

A disadvantage of the foregoing UHMW polymer as protective layer is that it is not chemically stable in all types of liquid electrolytes, in particular in certain organic solvents used in liquid electrolytes, and is prone to swelling. A further disadvantage is that the repelling ability of the UHMW polymer for the solvent in the electrolyte lead to an unstable and variable ionic conductivity of the lithium ion in the electrolyte.

### SUMMARY OF THE INVENTION

It is an aim of the present invention to overcome one or more of the foregoing drawbacks. It is an aim of the present invention to provide a lithium metal anode having excellent electrochemical performance. It is a further aim to provide a lithium metal anode having an improved lifetime, when used in a battery. Yet another aim is to provide a lithium metal anode which, in use in a battery, is less prone to dendrite formation and/or to the accumulation of dead lithium, thereby offering an excellent performance in secondary batteries. It is a further aim to provide a lithium metal anode which is chemically stable and/or which is mechanically robust and/or stable, in particular which can resist high mechanical stress, pressure and impact.

It is a further aim to provide a lithium metal anode for which the purity of the lithium metal is not critical for obtaining an excellent performance.

It is a further aim of the present invention to provide a lithium-ion battery which has an improved cycle lifetime, i.e, which can resist a large number of charging/discharging cycles.

According to a first aspect of the present disclosure, there is provided a lithium metal anode for a battery as set out in the appended claims. The lithium metal anode comprises an anode active substrate comprising lithium metal and a first lithium metal anode protective layer provided on a surface of the anode active substrate. The anode further comprises one or more of lithium carbonate (Li₂CO₃), lithium oxide (Li₂O) and lithium hydroxide (LiOH).

The lithium metal anode protective layer comprises or substantially consists of a first halide of lithium. Advantageously, the first halide of lithium is lithium iodide (LiI) or lithium fluoride (LiF).

Advantageously, the anode further comprises a second lithium metal anode protective layer provided on the first lithium metal anode protective layer. Advantageously, the second lithium metal anode protective layer comprises or substantially consists of a second halide of lithium. Advantageously, the second halide of lithium is LiI or LiF.

Advantageously, when the first and/or optional second lithium metal anode protective layer comprises or substantially consists of LiI, the respective lithium metal anode protective layer(s) has (have) a thickness between 5 nm and 800 nm, preferably between 50 nm and 700 nm, more preferably between 100 nm and 500 nm.

The inventors have surprisingly discovered that when the thickness of the protective layer(s) comprising or substantially consisting of LiI exceed 800 nm, the efficiency of Li-ion batteries comprising the respective inventive anode decreases to values that are considered inacceptable. More particularly, thicknesses higher than 800 nm may even lead to lithium plating/stripping, and thus charging/discharging of the battery becoming impossible, or of very low quality, while for thicknesses below 800 nm excellent lithium plating/stripping is possible.

Advantageously, when the first and/or optional second lithium metal anode protective layer comprises or substantially consists of LiF, the respective lithium metal anode protective layer(s) has (have) a thickness between 50 nm and 200 nm, preferably between 75 nm and 175 nm, more preferably between 100 nm and 150 nm.

The inventors have discovered that a thickness of the protective layer(s) comprising or substantially consisting of LiF of at least 50 nm is required to obtain a sufficient degree of protection of the anode active substrate, in particular in terms of reduction of formation of dendrite and/or accumulation of dead lithium when the anode is used in a battery. The inventors have further surprisingly discovered that when the thickness of the protective layer(s) comprising or substantially consisting of LiF exceeds 200 nm, lithium ion diffusion is impeded, i.e. becomes more difficult, and/or the internal resistance of the battery comprising the respective anode increases to levels that render the battery unusable.

Advantageously, the anode comprises a first and a second lithium metal anode protective layer, wherein the first lithium metal anode protective layer comprises or substantially consists of LiI, i.e, wherein the first halide of lithium comprises or substantially consists of LiI, and wherein the second lithium metal anode protective layer comprises or substantially consists of LiF, i.e, wherein the second halide of lithium comprises or substantially consists of LiF.

Advantageously, the anode active substrate comprises an anode current collector and a layer comprising or substantially consisting of lithium metal provided on a surface of the anode current collector. The anode current collector can be any anode current collector known in the field, in particular a copper substrate, such as a copper film.

Advantageously, the one or more of Li₂CO₃, Li₂O and LiOH comprised in the anode is (are) present as a native layer of impurities, wherein the native layer of impurities is comprised in the anode active substrate. More particularly, and advantageously, the native layer of impurities is present on the layer comprising or substantially consisting of lithium metal.

The term “native layer of impurities” is used in the present disclosure to indicate a layer of impurities which is inherently present on lithium metal, in particularly on commercially available lithium metal. This is a phenomenon that is known in the art, because lithium metal is very reactive in the ambient atmosphere, resulting in the formation of a native layer of impurities including one or more of carbonates, oxides, hydroxides and nitrides. It is further known that any lithium nitrides formed will over time convert into lithium carbonates and lithium hydroxides when exposed to, or in presence of CO₂ and water.

Alternatively, yet advantageously, the one or more of Li₂CO₃, Li₂O and LiOH comprised in the anode is (are) present as a passivation layer provided between the anode active substrate and the first lithium metal anode protective layer. When the anode active substrate comprises an anode current collector and a layer comprising or substantially consisting of lithium metal provided on a surface of the anode current collector, the passivation layer is advantageously provided between the layer comprising or substantially consisting of lithium metal and the first lithium metal anode protective layer.

The term “passivation layer” is used in the present disclosure for a separate layer present on the anode active substrate, and in particular on the lithium metal thereof, and mimicking in a controlled way the native layer of impurities present on lithium metal. In other words, the passivation layer comprises or substantially consists of the same components as the native layer of impurities, but contrary to the native layer, the passivation layer is a layer that is actively deposited so as to control its composition and structure.

The inventors have surprisingly discovered that the presence of such a passivation layer instead of the native layer of impurities, allows a more controlled, e.g. a more uniform and homogeneous, lithium plating and stripping of the anode. This in turn increase the number of lithium plating/stripping cycles the anode can withstand, thereby improving the lifetime of the anode. The passivation layer of the present invention further contributes to an improved electrochemical stability. Consequently, the passivation layer surprisingly improves the performance of the lithium metal anode, thereby improving the performance and lifetime of batteries comprising the lithium metal anode.

Advantageously, the passivation layer comprises the one or more of Li₂CO₃, Li₂O and LiOH.

Advantageously, the surface of the passivation layer adjacent to the first lithium metal anode protective layer comprises at least 80%, preferably at least 85%, more preferably at least 90% of one or more of Li₂O, LiOH and LiₓPO_{y}N_{z} (LIPON), wherein x, y and z, individually are greater than 0, as measured by quantification X-ray photoelectron spectroscopy (XPS). Advantageously, the surface of the passivation layer adjacent to the first lithium metal anode protective layer comprises at most 5%, preferably at most 3% of Li₂CO₃, as measured by quantification XPS.

With “the surface of the passivation layer” is meant in the present disclosure a portion of the passivation layer starting from the respective surface thereof, and having a thickness up to 20 nm, preferably up to 15 nm, more preferably up to 10 nm. It is known that surface analysis techniques, such as quantification XPS, typically probe up to a thickness of 10 nm to 20 nm, i.e, the portion considered as the surface, surface layer or surface portion.

With “the bulk (portion) of the passivation layer” is meant in the present disclosure the portion of the passivation layer starting at a thickness of 20 nm, preferably 15 nm, more preferably 10 nm all the way to the end of the passivation layer. In other words, the passivation layer can be considered to have a surface or surface portion and a bulk or bulk portion.

Advantageously, the passivation layer has a thickness between 100 nm and 1000 nm, preferably between 150 nm and 900 nm, more preferably between 200 nm and 800 nm, for example between 250 nm and 750 nm, or between 500 nm and 700 nm.

Advantageously, the surface of the passivation layer adjacent to the first lithium metal anode protective layer comprises or substantially consists of Li₂CO₃, Li₂O and LiOH, i.e. at the first 10 nm thickness starting from the surface of the passivation layer adjacent to the first lithium metal anode protective layer, as measured by the total electron yield (TEY) signal of X-ray absorption Spectroscopy (XAS).

Advantageously, and preferably additionally, the bulk of the passivation layer comprises or substantially consists of Li₂O and/or LiOH, as measured by the total fluorescence yield (TFY) signal of XAS.

According to a second aspect of the present disclosure, there is provided a lithium-ion battery as set out in the appended claims. Advantageously, the lithium-ion battery comprises the anode of the first aspect of the invention. Advantageously, the battery is a secondary battery.

According to a third aspect of the present disclosure, there is provided a method of producing a lithium metal anode as set out in the appended claims. Advantageously, the lithium metal anode is an anode for a battery.

Advantageously, the lithium metal anode is according to the first aspect of the invention. In other words, the lithium metal anode advantageously comprises an anode active substrate and a first lithium metal anode protective layer as described hereinabove, i.e, the first lithium metal anode protective layer comprising a first halide of lithium and provided on a surface of the anode active substrate.

The method comprises depositing a first lithium metal anode protective layer on a surface of an anode active substrate comprising lithium metal. The first lithium metal anode protective layer is deposited by means of thermal evaporation of a first coating composition. The first coating composition comprises or substantially consists of a first halide of lithium.

Advantageously, the first coating composition has a temperature between 200° C. and 1000° C., preferably between 200° C. and 900° C., more preferably between 250° C. and 750° C. during the thermal evaporation thereof on the surface of the anode active substrate. Advantageously, the anode active substrate has a temperature between 10° C. and 30° C., preferably between 15° C. and 25° C., more preferably room temperature, e.g. 20° C., during the thermal evaporation of the first coating composition.

Advantageously, the method further comprises depositing a second lithium metal anode protective layer on first lithium metal anode protective layer. The second lithium metal anode protective layer is deposited by means of thermal evaporation of a second coating composition. The second coating composition comprises or substantially consists of a second halide of lithium.

Advantageously, the second coating composition has a temperature between 200° C. and 1000° C., preferably between 200° C. and 900° C., more preferably between 250° C. and 750° C. during the thermal evaporation thereof on the surface of the first lithium metal anode protective layer. Advantageously, the anode active substrate has a temperature between 10° C. and 30° C., preferably between 15° C. and 25° C., more preferably room temperature, e.g. 20° C., during the thermal evaporation of the second coating composition.

Advantageously, the first and the optional second halide of lithium are as described hereinabove, i.e. they are, individually, LiI or LiF.

Advantageously, when the first halide of lithium and/or the optional second halide of lithium is (are) LiI, the respective coating composition(s)—i.e, the respective coating composition(s) comprising or substantially consisting of LiI—has (have) a temperature between 250° C. and 400° C., preferably between 275° C. and 375° C., more preferably between 300° C. and 350° C. during the respective thermal evaporation thereof.

Advantageously, when the first halide of lithium and/or the optional second halide of lithium is (are) LiF, the respective coating composition(s)—i.e, the respective coating composition(s) comprising or substantially consisting of LiF—has (have) a temperature between 500° C. and 900° C., preferably between 600° C. and 850° C., more preferably between 700° C. and 800° C. during the respective thermal evaporation thereof.

Advantageously, the thermal evaporation of the first coating composition and/or the optional second coating composition, individually, is conducted between 1 and 50 times, preferably between 5 and 30 times, more preferably between 10 and 20 times. In particular, the thermal evaporation is conducted the number of times required to obtain a predetermined thickness of the lithium metal anode protective layer. It will be understood that the number of repetitions depends on the predetermined thickness to be obtained, as well as on the thickness deposited with each repetition.

Advantageously, the method further comprises a step of gas assisted radio frequency (RF) sputtering using a target substrate, prior to deposition of the first lithium metal anode protective layer. Advantageously, the target substrate, in short target, comprises or substantially consists of Li₃PO₄ (LiPO).

Advantageously, the gas assisted RF sputtering converts any native layer of impurities present on the anode active substrate to a passivation layer on the anode active substrate, wherein the passivation layer is as described hereinabove.

Advantageously, the gas is nitrogen, argon, helium or a combination of two or more thereof. Particularly preferred examples of the gas include nitrogen and a mixture of nitrogen with an inert gas.

Advantageously, the target substrate comprising or substantially consisting of Li₃PO₄ has a temperature between 10° C. and 50° C., preferably between 15° C. and 35° C., more preferably between 20° C. and 30° C., for example room temperature, e.g. 20° C., during the gas assisted RF sputtering.

Advantageously, the gas assisted RF sputtering has a duration between 5 minutes and 2.5 hours, preferably between 5 minutes and 60 minutes, more preferably between 10 minutes and 30 minutes.

### DESCRIPTION OF THE FIGURES

Aspects of the invention will now be described in more detail with reference to the appended drawings, wherein same reference numerals illustrate same features and wherein:

FIGS. 1 to 6 schematically show a first, second, third, fourth, fifth, and sixth lithium metal anode according to the invention, respectively;

FIGS. 7 and 8 show the repeated charging/discharging behaviour in function of the number of charging/discharging cycles for a reference battery and a battery comprising a first and a second inventive anode, respectively;

FIG. 9 shows the in-situ XPS survey spectra for the lithium metal without and with an inventive passivation layer;

FIG. 10 shows the in-situ XPS at the O1s core level for the lithium metal without and with an inventive passivation layer;

FIG. 11 shows the XAS-spectra at the O K-edge in TEY and TFY modes for the anode with a passivation layer;

FIG. 12 shows the voltage profile for an inventive symmetrical cell and a reference symmetrical cell in function of time/the number of charging/discharging cycles at a 1.0 mA/cm² current density and a 1.5 mAh/cm² areal capacity;

FIG. 13 shows the voltage profile for an inventive symmetrical cell and a reference symmetrical cell in function of time/the number of charging/discharging cycles at a 2.0 mA/cm² current density and a 1.5 mAh/cm² areal capacity;

FIGS. 14A and 14B show SEM-images of the surface of a reference anode after repeated lithium stripping/plating;

FIGS. 15A and 15B show SEM-images of the surface of an inventive anode after repeated lithium stripping/plating;

FIG. 16 shows the discharge capacity and the Coulombic efficiency of a reference battery cell;

FIG. 17 shows the discharge capacity and the Coulombic efficiency of an inventive battery cell; and

FIG. 18 shows the charge capacity of inventive and reference pouch cells in function of the number of charging/discharging cycles using 0.7 mA/cm² charging current density and a 2.2 mA/cm² discharge current density and a 2.2 mAh/cm² areal capacity.

### DETAILED DESCRIPTION OF THE INVENTION

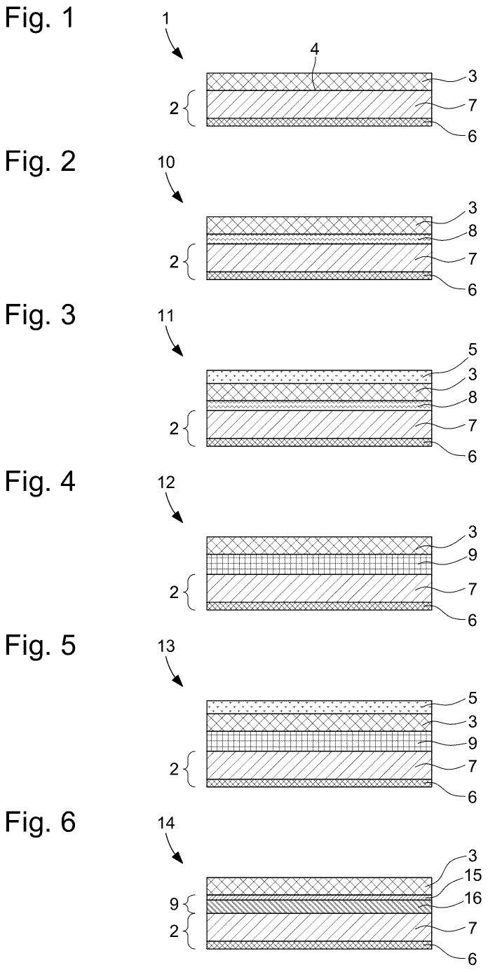

FIG. 1 shows a schematical representation of an anode 1 according to the present invention. The anode 1 comprises an anode active substrate 2. The anode active substrate 2 comprises an anode current collector 6 and a layer 7 comprising or substantially consisting of lithium metal. The anode current collector 6 can be any anode current collector known in the art, in particular for lithium-ion batteries.

The anode 1 further comprises a first lithium metal anode protective layer 3, which is provided on a surface 4 of the anode active substrate 2, in particular on the surface of the layer 7 comprising of substantially consisting of lithium metal opposite to the surface thereof adjacent to, or contacting the anode current collector 6.

The first lithium metal anode protective layer 3 comprises or substantially consists of a first halide of lithium. The first halide of lithium advantageously is lithium iodide (LiI) or lithium fluoride (LiF).

The first lithium metal anode protective layer 3 can comprise or substantially consist of two or more halides of lithium. For example, the first lithium metal anode protective layer 3 can comprise two halides of lithium. When the first lithium metal anode protective layer 3 comprises two halides of lithium, the halides of lithium are advantageously LiI and LiF.

FIG. 2 shows a second anode 10 of the present invention. The difference between the anode 10 of FIG. 2 and the anode 1 of FIG. 1 is that the anode active substrate 2 of the anode 10 of FIG. 2 further comprises a native layer of impurities 8. The native layer of impurities 8 is thus present between the layer 7 comprising of substantially consisting of lithium metal and the first lithium metal anode protective layer 3.

The native layer of impurities 8 is advantageously as known in the art. Advantageously, the native layer of impurities 8 comprises or substantially consists of one or more of lithium carbonate (Li₂CO₃), lithium oxide (Li₂O) and lithium hydroxide (LiOH).

FIG. 3 shows a further anode 11 of the present invention. The difference between the anode 11 of FIG. 3 and the anode 10 of FIG. 2 is that the anode 11 of FIG. 3 further comprises a second lithium metal anode protective layer 5. The second lithium metal anode protective layer 5 is provided on the first lithium metal anode protective layer 3.

The second lithium metal anode protective layer 5 comprises or substantially consists of a second halide of lithium. The second halide of lithium advantageously is lithium iodide (LiI) or lithium fluoride (LiF).

The second lithium metal anode protective layer 5 can comprise or substantially consist of two or more halides of lithium. For example, the second lithium metal anode protective layer 5 can comprise two halides of lithium. When the second lithium metal anode protective layer 5 comprises two halides of lithium, the halides of lithium are advantageously LiI and LiF.

A non-limiting example of an anode 11 according to FIG. 3 is one wherein the first lithium metal anode protective layer 3 comprises or substantially consists of LiI, and wherein the second lithium metal anode protective layer 5 comprises or substantially consists of LiF.

Another non-limiting example of an anode 11 according to FIG. 3 is one wherein the first lithium metal anode protective layer 3 comprises or substantially consists of LiI and LiF, and wherein the second lithium metal anode protective layer 5 comprises or substantially consists of LiF.

Optionally, the anode 11 further comprises one or more further lithium metal anode protective layer(s), i.e. a third, fourth, fifth, sixth, or more lithium metal anode protective layer(s) (not shown). Advantageously, each further lithium metal anode protective layer, individually, comprises or substantially consists a further halide of lithium. Advantageously, each one of the further halide(s) of lithium, individually, is LiI or LiF.

The one or more further lithium metal anode protective layer(s), individually, can comprise or substantially consist of two or more halides of lithium. In other words, each of the optional one or more further lithium metal anode protective layer(s) can comprise, individually, one, two, or even more, halide(s) of lithium.

Advantageously, the total thickness of the lithium metal anode protective layers is between 5 nm and 2.5 μm, preferably between 10 nm and 2 μm, more preferably between 50 nm and 1.5 μm.

The term “total thickness of the lithium metal anode protective layers” is used in the present disclosure for the thickness of the first lithium metal anode protective layer (3) when there is no further lithium metal anode protective layer (for example the anodes of FIG. 1 and FIG. 2), or the sum of the thickness of each lithium metal anode protective layer when there are two or more lithium metal anode protective layers (for example the anode of FIG. 3).

FIG. 4 shows yet another anode 12 of the present invention. The anode 12 of FIG. 4 differs from the anode 1 of FIG. 1 in that the anode 12 comprises a passivation layer 9. The passivation layer 9 is present between the anode active substrate 2, in particular the layer 7 comprising of substantially consisting of lithium metal, and the first lithium metal anode protective layer 3.

In other words, the anode 12 of FIG. 4 differs from the anode 10 of FIG. 2 in that the native layer of impurities 8 is replaced by the passivation layer 9. The passivation layer comprises or substantially consists of one or more of Li₂CO₃, Li₂O and LiOH and LiₓPO_{y}N_{z} (LIPON), wherein x, y and z, individually, are higher than 0.

Advantageously, the surface of the passivation layer 9 adjacent to the first lithium metal anode protective layer 3 comprises at least 70%, preferably at least 80%, for example at least 85%, more preferably at least 90%, or at least 95%, of one or more of Li₂O, LiOH and LIPON, as measured by quantification X-ray photoelectron spectroscopy (XPS).

Advantageously, the surface of the passivation layer 9 adjacent to the first lithium metal anode protective layer 3 comprises at most 5%, preferably at most 4%, more preferably at most 3%, most preferably at most 2%, of Li₂CO₃, as measured by quantification XPS.

Whereas during the battery cycling, Li₂CO₃ chemically or electrochemically reacts with the electrolyte, causing electrolyte degradation and rapid failure of a battery, the inventors have surprisingly discovered that the passivation layer 9, comprising, at its surface adjacent to the first lithium metal anode protective layer 3, at most 5% of Li₂CO₃, does not show this behaviour. Without wishing to be bound by any theory, the inventors believe that this is a combination of the low amount (at most 5%) of Li₂CO₃ present in the passivation layer and the controlled and robust structure of the passivation layer, as compared to the more random structure of the native layer.

Consequently, the passivation layer 9 allows for a more controlled, e.g. a more uniform and homogeneous, lithium plating and stripping of the anode. This in turn increase the number of lithium plating/stripping cycles the anode can withstand, thereby improving the cycling lifetime of the anode.

The passivation layer of the present invention further contributes to an improved electrochemical stability. Consequently, the passivation layer surprisingly improves the performance of the lithium metal anode, thereby improving the performance and cycling lifetime of batteries comprising the lithium metal anode.

Advantageously, the passivation layer has a thickness between 100 nm and 1000 nm, preferably between 125 nm and 750 nm, more preferably between 150 nm and 500 nm, such as between 175 nm and 400 nm, or between 200 nm and 300 nm.

FIG. 5 shows another anode 13 of the present invention. The anode 13 of FIG. 5 differs from the anode 12 of FIG. 4 in that it comprises a second lithium metal anode protective layer 5 on the first lithium metal anode protective layer 3. The second lithium metal anode protective layer 5 is as described hereinabove. The anode 13 can comprise further lithium metal anode protective layers (not shown), such as a third, fourth or fifth lithium metal anode protective layer, which are also as described hereinabove.

FIG. 6 shows another anode 14 of the present invention. The anode 14 of FIG. 6 differs from the anode 12 of FIG. 4 in that the passivation layer 9 comprises or substantially consists of a first sublayer 15, i.e, the surface of the passivation layer 9, and a second sublayer 16, i.e, the bulk of the passivation layer 9, wherein the first sublayer 15 is adjacent to the first lithium metal anode protective layer 3 and the second sublayer 16 is adjacent to the anode active substrate 2.

Advantageously, the first sublayer 15 comprises or substantially consists of Li₂CO₃, Li₂O and LiOH, as measured by the total electron yield (TEY) signal of XAS. Advantageously, the first sublayer 15 has a thickness between 1 nm and 20 nm, preferably between 2 nm and 15 nm, more preferably between 5 nm and 12 nm, such as 10 nm.

Advantageously, the second sublayer 16 comprises or substantially consists of Li₂O and/or LiOH, as measured by the total fluorescence yield (TFY) signal of XAS.

Without wishing to be bound by any theory, the inventors believe that when the passivation layer 9 comprises or substantially consists of a first 15 and a second 16 sublayer, a synergy is realised between both sublayers, leading to a more robust anode and thus an improved lithium plating/stripping resistance when compared to anodes without passivation layer and even to anodes with a passivation layer not having this structural set-up. This results in batteries having an excellent cycle lifetime, outperforming batteries having anodes without a passivation layer.

The present invention further relates to batteries, in particular lithium-ion batteries, comprising the inventive anodes. Advantageously, the (lithium-ion) battery is a secondary (lithium-ion) battery.

The battery further comprises a cathode. The cathode can be any cathode known in the field. Advantageously, the cathode comprises a cathode current collector, which can be any cathode current collector known in the field, and a cathode active material. Non-limiting examples of cathode active materials include vanadates, such as H₂V₃O₈, NMC and LiFePO₄ (LFP).

The battery further comprises an electrolyte. The electrolyte can be a liquid electrolyte or a solid electrolyte. The electrolyte can be any electrolyte known in the art, such as the liquid electrolyte comprising Lithium Bis(fluorosulfonyl)imide (LiFSI) in dimethoxyethane (DME), for example a 2 M LiFSI in DME electrolyte.

The battery can further comprise a separator, in particular when the electrolyte is a liquid electrolyte. The separator can be any separator known in the field.

The present invention further relates to methods of producing the inventive anodes. The methods comprise an operation of providing an anode active substrate 2, optionally a step of gas assisted radio-frequency (RF) sputtering, and an operation of thermal evaporation of at least a first coating composition.

First, an anode active substrate 2 is provided, wherein the anode active substrate is as described hereinabove, for example and in particular comprising an anode current collector 6 and a layer 7 comprising or substantially consisting of lithium metal. The layer 7 can further comprise one or more of Li₂CO₃, Li₂O and LiOH.

Advantageously, the anode active substrate further comprises a native layer of impurities 8 prior to the optional sputtering and the thermal evaporation steps. The native layer of impurities 8 is as described hereinabove.

A first lithium metal anode protective layer 3 is deposited on the anode active substrate 2, in particular on the layer 7 comprising or substantially consisting of lithium metal, or, when present, on the native layer of impurities 8, thereby obtaining the anode 1 of FIG. 1 (no native layer of impurities) or the anode 10 of FIG. 2 (with native layer of impurities 8).

The first lithium metal anode protective layer 3 is deposited on the anode active substrate 2 by means of thermal evaporation of a first coating composition. The first coating composition comprises a first halide of lithium. Advantageously, the first halide of lithium is LiI or LiF.

Advantageously, the thermal evaporation is performed under vacuum. To this end, the anode active substrate to be treated is placed in a reaction chamber, which is then brought to a predetermined pressure below atmospheric pressure. Advantageously, the thermal evaporation is performed at ultra-high vacuum, i.e. at a working pressure within the reaction chamber of at most 10⁻⁶ mbar.

Advantageously, the anode active substrate is at room temperature during the thermal evaporation.

The thermal evaporation of the first coating composition comprises heating the first coating composition to a temperature so that the first halide of lithium evaporates. The evaporated first halide of lithium then condenses on the anode active substrate, thereby forming the first lithium metal anode protective layer. The first lithium metal anode protective layer thus comprises or substantially consists of the first halide of lithium.

Advantageously, when the halide of lithium is LiI, the respective coating composition has a temperature between 150° C. and 400° C. during the thermal evaporation thereof.

Advantageously, when the halide of lithium is LiF, the respective coating composition has a temperature between 500° C. and 900° C. during the thermal evaporation thereof.

Optionally, when the first lithium metal anode protective layer 3 is to comprise a further halide of lithium, there is provided a further coating composition comprising a further halide of lithium. The first and the further coating compositions are then thermally evaporated simultaneously, thereby (co-)depositing a first lithium metal anode protective layer comprising the first and the further halides of lithium.

For example, when the first lithium metal anode protective layer 3 is to comprise or substantially consist of a combination of LiI and LiF, a first coating composition comprising or substantially consisting of LiI and a further coating composition comprising or substantially consisting of LiF are provided. Simultaneous thermal evaporation is then performed, wherein the first coating composition has a temperature between 150° C. and 400° C. and the further coating composition has a temperature between 500° C. and 900° C. during the simultaneous thermal deposition (i.e. thermal co-deposition) thereof, thereby obtaining the first lithium metal anode protective layer comprising or substantially consisting of LiI and LiF.

Advantageously, a second lithium metal anode protective layer 5 can be obtained on the first lithium metal anode protective layer 3 by thermal evaporation of a second coating composition comprising a second halide of lithium, thereby obtaining the anode 11 of FIG. 3. Advantageously, the second halide of lithium is LiI or LiF. Advantageously, the anode active substrate is at room temperature during the thermal evaporation.

Advantageously, the thermal evaporation to obtain or deposit the second lithium metal anode protective layer 5 is performed as described hereinabove for the first lithium metal anode protective layer 3. In particular, to deposit a first 3 and a second 5 lithium metal anode protective layer 5, sequential thermal evaporation is performed, i.e. in a first step the thermal evaporation of a first coating composition to deposit the first protective layer 3, followed by (in a second step) the thermal evaporation of a second coating composition to deposit the second protective layer 5.

Optionally, when the second lithium metal anode protective layer 3 is to comprise a further halide of lithium, there is provided a further coating composition comprising a further halide of lithium. The second and the further coating compositions are then thermally evaporated simultaneously, thereby depositing a second lithium metal anode protective layer comprising the second and the further halides of lithium.

Optionally, more lithium metal anode protective layers, e.g. a third, fourth or fifth lithium metal anode protective layer, can be deposited in a way similar to the first and the second lithium metal anode protective layers 3,5.

Optionally, prior to the deposition of the first lithium metal anode protective layer 3, a passivation layer can be provided on the anode active substrate 2, in particular on the layer 7 comprising or substantially consisting of lithium metal.

When the anode active substrate 2 comprises a layer of impurities 8 on the layer 7 comprising or substantially consisting of lithium metal, the layer of impurities 8 is advantageously converted into the passivation layer 9 during provision thereof. The passivation layer 9 is advantageously as described hereinabove.

The passivation layer 9 is obtained by means of gas assisted radio-frequency (RF) sputtering using a target. Advantageously, the target, in short target, comprises or substantially consists of Li₃PO₄ (LiPO).

Advantageously, the gas is nitrogen, argon, helium or a combination of two or more thereof.

The gas assisted RF sputtering is advantageously performed in vacuum, i.e. at a pressure below atmospheric pressure, advantageously a pressure around 10⁻³ mbar.

Advantageously, the RF sputtering is performed at a frequency between 30 Hz and 300 GHz, preferably in at a frequency in the MHz range, in particular at a frequency of 13.56 MHz.

Advantageously, the gas assisted RF sputtering comprises igniting a plasma of the gas. Upon igniting the gas plasma, the ions in the plasma interact, i.e. react, with the LiPO target, thereby generating reactive oxidative species such as O*, N* and PO₄*. These reactive oxidative species then react with at least a portion, and advantageously substantially all, of the Li₂CO₃ present in the anode active substrate, thereby forming a passivation layer comprising or substantially consisting of one or more of Li₂O, LiOH and LiₓPO_{y}N_{z} (LIPON), wherein x, y and z, individually, are higher than 0.

With “at least a portion of the Li₂CO₃” is meant in the present disclosure that at most 10%, preferably at most 5%, more preferably at most 3% of the Li₂CO₃ does not react with the reactive oxidative species, and is consequently present in the surface of the passivation layer opposite to the surface of the passivation layer adjacent to the anode active substrate, i.e. for a thickness up to 20 nm, preferably up to 15 nm, more preferably up to 10 nm.

Advantageously, when Li₂CO₃ is present in the layer 7 comprising of substantially consisting of lithium metal, the passivation layer is formed on the anode active substrate 2, in particular on the layer 7 comprising or substantially consisting of lithium metal.

Advantageously, when Li₂CO₃ is present in a native layer of impurities 8, the reactive oxidative species convert this native layer 8 during the sputtering process, thereby obtaining the passivation layer 9 on the layer 7 comprising or substantially consisting of lithium metal of the anode active substrate 2.

Once the passivation layer 9 is formed, a first lithium metal anode protective layer 3 is deposited on the passivation layer 9 by means of thermal evaporation as described hereinabove, thereby obtaining the anodes 12, 14 of FIG. 4 and FIG. 6.

Optionally, a second lithium metal anode protective layer 5 can be deposited on the first lithium metal anode protective layer 3 by means of thermal evaporation as described hereinabove, thereby obtaining the anode 13 of FIG. 5. Optionally, further lithium metal anode protective layers can further be deposited, by means of thermal evaporation as described hereinabove.

### EXAMPLES

### Example 1

A first anode was prepared by depositing a layer of lithium iodide (LiI) on an anode active substrate that was commercially purchased and consisted of a 13 μm thick copper foil as current collector with a 50 μm thick layer of lithium metal and a native layer of Li₂CO₃. The deposition was performed by depositing a coating composition substantially consisting of lithium iodide (LiI) on the lithium metal layer by means of thermal evaporation at 350° C. in a processing chamber operating at ultra-high vacuum (UHV). A thermal evaporation source (i.e. coating composition) containing LiI was used. The deposition step was conducted 20 times, thereby obtaining a LiI layer having a thickness of 800 nm.

A second anode was prepared, again in UHV conditions, by depositing first a layer of LiI on the same copper foil with a 50 μm thick layer of lithium metal, followed by deposition of a layer of LiF. The LiI layer was deposited on the lithium metal layer by thermal evaporation at 350° C. using a thermal evaporation source containing LiI. The depositions were conducted until a the LiI layer had a thickness of 800 nm. The LiF layer was deposited on the LiI layer by thermal evaporation at 800° C. A thermal evaporation source containing LiF was used. The depositions were conducted until the LiF layer had a thickness of 200 nm. Both depositions were performed in the same processing chamber without breaking the UHV in order to prevent any possible contamination between the subsequent depositions.

Next, first and second inventive lithium ion batteries were prepared, comprising the first and second anodes of the invention. A LiFePO₄ (LFP) cathode was used, and the electrolyte was 2 M lithium bis(fluorosulfonyl)imide (LiFSI) salt in an ether based electrolyte.

A reference lithium ion battery was prepared as well, having the same cathode and electrolyte as the first and second inventive lithium ion batteries, but the commercial anode active substrate (13 μm thick copper foil as current collector with a 50 μm thick layer of lithium metal and a native layer of Li₂CO₃) without any further treatment as anode.

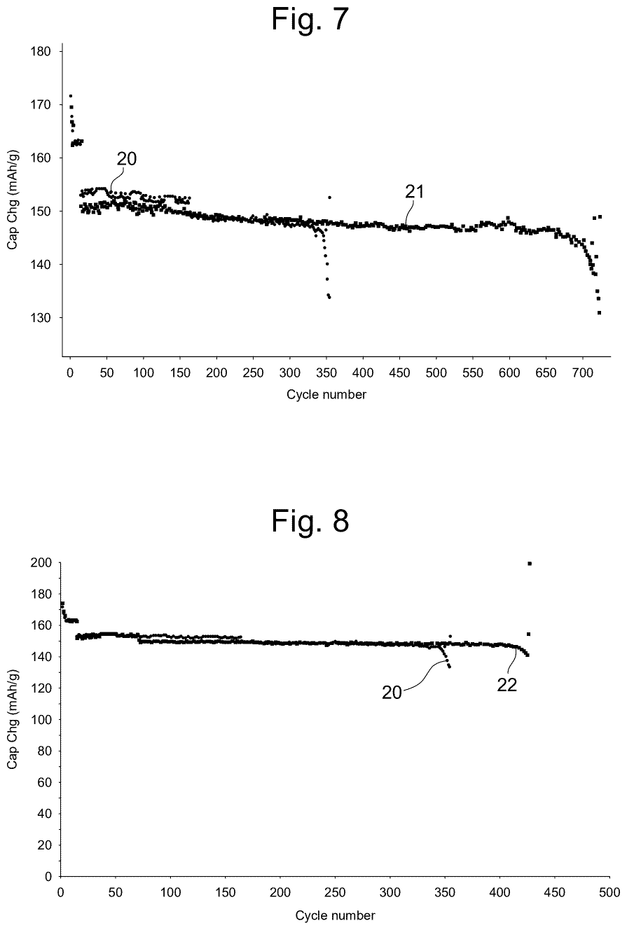

The batteries were then repeatedly charged and discharged. Charging was performed at 4.3 mA until 3.8 V was reached. Discharging was performed at 13 mA until 2.2 V was reached. FIG. 7 shows the specific charge capacity in function of the number of charging/discharging cycles for the reference battery 20 and the first inventive battery 21 (800 nm LiI layer). It is clear that the reference battery shows a clear decrease in performance after 340 charging/discharging cycles, whereas the first inventive battery remains stable for almost 700 cycles. FIG. 8 shows the specific charge capacity in function of the number of charging/discharging cycles for the reference battery 20 and the second battery 22. It is clear that the reference battery shows a clear decrease in performance after 340 charging/discharging cycles, whereas the second inventive battery remains stable for almost 450 cycles.

### Example 2

The same copper foil with a 50 μm thick layer of lithium metal as in Example 1 was used as anode active substrate. It is known that lithium is reactive if exposed to air and moisture, leading to the lithium being covered with carbonates, oxides and hydroxides. More specifically, the lithium metal is known to be covered with a native layer primarily comprising Li₂CO₃.

Nitrogen assisted radio frequency (RF) sputtering was performed on the lithium metal to convert the native layer, i.e. to convert the Li₂CO₃ to Li₂O. A sintered Li₃PO₄ pellet was used as sputtering target and was placed in the sputtering equipment (Bdiscom, RF Generator 300W at 13.56 MHz), and a water cooler was connected to the Li₃PO₄ sputtering target to prevent overheating thereof. The sputtering target and the walls of the equipment were kept at room temperature. The anode active substrate was placed on a sample holder, both also at room temperature. After closing the processing chamber containing the target and anode active substrate, the processing chamber was evacuated and a pressure of 5*10⁻⁸ mbar (i.e. base pressure) was maintained to remove any humidity and volatile contaminants from the processing chamber. Then nitrogen was added to the chamber at a flow rate of 6 sccm, thereby increasing the pressure in the chamber to 1.5*10⁻² mbar (i.e. working pressure). A RF power of 30 W was applied to ignite the N₂ plasma for 5 minutes, i.e, the sputtering process has a duration of 5 minutes.

The nitrogen assisted sputtering was performed while the anode active substrate placed in the processing chamber “facing away” from the Li₃PO₄ target. In other words, the lithium metal was not directly exposed to the Li₃PO₄ target, i.e. indirect sputtering. This was realised by positioning the anode active substrate on the sample holder in such a way that the sample holder was positioned between the anode active substrate and the target.

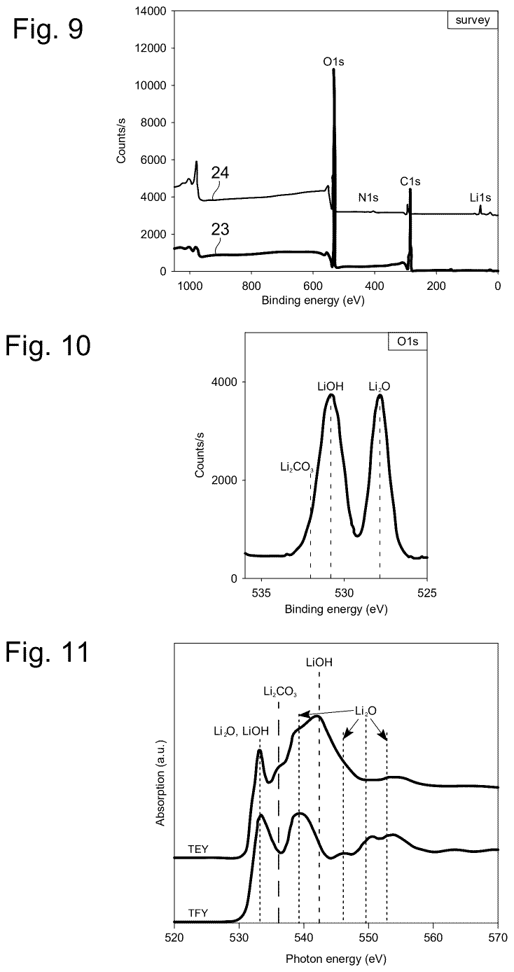

X-ray photoelectron spectroscopy (XPS) was performed in-situ to avoid any contamination of the surface of the lithium metal. XPS measurements were performed using a VG ESCALAB 220iXL spectrometer (Thermo Fisher Scientific) at a base pressure of ˜10⁻⁹ mbar with a focused monochromatized Al K radiation (1486.6 eV) and a beam size of 500 μm². FIG. 9 shows the in-situ XPS survey spectra for the lithium metal of the anode active substrate prior to (23) and after 5 minutes N₂ assisted RF sputtering (24). It is clear that the C1s peak after exposure to the N₂ plasma is much lower than the C1s peak of the untreated lithium metal, thereby confirming the successful conversion of most of the Li₂CO₃. FIG. 10 shows the in-situ XPS at the O1s core level for the lithium metal of the anode active substrate after 5 minutes N₂ assisted RF sputtering, from which it is clear that the surface of the lithium metal was covered by a passivation layer comprising mainly Li₂O and LiOH, and a small amount of Li₂CO₃, LiNOₓ and Li₃N.

The same experiment was repeated but by using argon instead of N₂ as the gas in the RF sputtering. Table 1 shows the atomic composition and the ratio of the components for the obtained passivation layer after nitrogen (N₂) assisted and argon (Ar) assisted sputtering, respectively. The element concentration and ratio of the components was based on the quantification of the XPS data. It is clear that in both surfaces of the passivation layers (i.e. the surface opposite to the surface of the passivation layer adjacent to the anode active substrate), the ratio of Li₂O and LiOH are the same, together amounting to more than 90% of the composition, while with argon a lower amount of residual Li₂CO₃ and a slightly higher amount of LiNOₓ was detected.

TABLE 1
Element concentration and component
ratio in passivation layer surface

| | N₂ assisted | Ar assisted |
|---|---|---|
| | sputtering | sputtering |
| Lithium (at. %) | 60.14 | 59.65 |
| Oxygen (at. %) | 36.62 | 37.35 |
| Phosphorous (at. %) | 0 | 0 |
| Nitrogen (at. %) | 0.65 | 1.85 |
| Carbon (at. %) | 2.59 | 1.16 |
| Ratio of components | 49.2%/41.3%/ | 49.9%/41.8%/ |
| Li₂O/LiOH/Li₂CO₃/NOₓ | 7.4%/2.1% | 3.1%/5.2% |

### Example 3

The same copper foil with a 50 μm thick layer of lithium metal as in Example 1 was used as anode active substrate. The same sputtering device and target was used for N₂ assisted RF sputtering on the lithium metal.

The anode active substrate and the sample holder were now placed in the processing chamber so that the lithium metal was facing towards the Li₃PO₄ sputtering target, i.e. direct sputtering was performed by means of this set-up.

After placing the anode active substrate in the chamber, the chamber was closed and its pressure was reduced to a base pressure of 5*10⁻⁸ mbar. Nitrogen was added to the chamber at a flow rate of 6 sccm, thereby increasing the pressure in the chamber to 1.4*10⁻² mbar (i.e. working pressure). A RF power of 35 W was applied to ignite the N₂ plasma. Different sputtering durations were performed: 5 min, 10 min, 15 min and 25 min.

In-situ XPS was again performed on the (exposed) surface of the passivation layer (i.e, the surface opposite to the surface of the passivation layer adjacent to the anode active substrate), and the XPS quantification allowed to determine the ratio of the components in the surface of the formed passivation layer, based on the atomic concentrations of the elements lithium, oxygen, nitrogen, phosphorous and carbon. The results are represented in Table 2. After sputtering durations up to 25 minutes, the surface of the passivation layer consisted mainly of Li₂O and LiOH. A sputtering duration of 25 minutes was considered to give the best results, because the surface of the respective passivation layer showed the lowest concentration of Li₂CO₃ when compared to the surface of the passivation layers obtained with shorter and longer sputtering times.

TABLE 2
ratio of components of surface of passivation layer

| Sputtering | | | | |
|---|---|---|---|---|
| duration | Li2O (%) | LiOH (%) | LiₓPO_{y}N_{z} (%) | Li₂CO₃ (%) |
| 5 min | 55.8 | 40.7 | 1.3 | 2.2 |
| 10 min | 53.2 | 44.1 | 1.0 | 1.7 |
| 15 min | 62.9 | 34.6 | 1.2 | 1.3 |
| 25 min | 54.1 | 36.5 | 5.8 | 2.6 |

The same procedure was also repeated but for sputtering times of 50 minutes and 2.5 hours. It was unexpectedly noticed that the XPS quantification did not allow any more to distinguish between LiOH and LiₓPO_{y}N_{z}. It is believed that this is because with an increasing LiₓPO_{y}N_{z} concentration, the O1s peak that allows to quantify LiOH starts to overlap with the signal from the LiₓPO_{y}N_{z}.

The surface of the passivation layer obtained by 50 minutes sputtering showed the following ratio of components: 45% LiO, 52% LiOH+LiₓPO_{y}N_{z}, and 3% Li₂CO₃. The surface of the passivation layer obtained by 2.5 hours sputtering showed the following ratio of components: 29% LiO, 68% LiOH+LiₓPO_{y}N_{z}, and 3% Li₂CO₃.

Next, a 90 nm thick layer of LiF was deposited on the passivation layer obtained with 25 min sputtering. The LiF layer was deposited by thermal evaporation at 800° C. A thermal evaporation source containing LiF was used. By depositing this LiF layer, lithium metal anodes according to the invention were obtained.

The thickness of the passivation layer and the LiF protective layer was determined by the cross-section scanning electron microscopy (SEM) image after bending the anode and breaking both the passivation layer and the LiF layer. The SEM images were taken with a 5 kV acceleration voltage using a scanning electron microscope (Zeiss Gemini) (in-lens and secondary electron detectors). It was found that after 25 minutes sputtering, followed by the deposition of a LiF protective layer, the total thickness, i.e, the thickness of the passivation layer was around 700 nm.

The passivation layer of the anode, obtained by 25 min sputtering, was further analysed by X-ray absorption spectroscopy (XAS) to evaluate the composition at the surface of the passivation layer and at the bulk of the passivation layer. All tests were carried out at the room temperature in ultrahigh vacuum (UHV; base pressure 5×10⁻⁹ mbar) by collecting secondary photoelectrons. Secondary electrons generated by the sample as a function of photon energy were captured using a picometer to measure the sample electron current (Keithley 6517B). The total electron yield (TEY) signal is generated by photoelectrons from a 10 nm thick surface layer. The total fluorescence yield (TFY) signal with a depth analysis of hundreds of nanometers has also been collected for comparing surface species to bulk components.

FIG. 11 shows the XAS-spectra at the O K-edge in TEY and TFY modes for the anode with the 25 min sputtering passivation layer. It is clear that Li₂CO₃ is detected only in TEY mode, indicating that the bulk phase of the passivation layer is substantially free from Li₂CO₃, whereas Li₂O and LiOH are present both at the surface and in the bulk phase of the passivation layer.

### Example 4

A symmetrical battery cell according to the invention was prepared using the anode of Example 2 having a passivation layer obtained by 25 min sputtering, but without the 90 nm LiF layer on top of the passivation layer. The anode was used for both electrodes of the symmetrical battery cell, and had a diameter of 13 mm.

A polypropylene separator foil (CG2400, Celgard LLC, USA) with a diameter of 17 mm was used as separator. 2:1 (v/v) mixture of DME and 1,3-dioxolane (DOL) with 1M lithium bis(trifluormethylsulfonyl)amid (LiTFSI) and a 0.5M LiNO₃ additive was used as the electrolyte. 100 μL of the electrolyte was injected into the symmetric cell according to the invention. The cell was closed with a torque wrench.

A reference symmetrical battery cell was prepared as well. The same 13 μm thick copper foil with a 50 μm thick layer of lithium metal of Example 1 was used as such as the electrodes. In other words the electrodes did not have a passivation layer and did not have any lithium metal anode protective layer. The same separator and electrolyte were used, and the cell was closed in the same way as the inventive symmetrical cell by providing same stack pressure.

Both symmetrical cells were assembled in an argon-filled glove box, containing less than 0.4 ppm O₂ and less than 0.8 ppm H₂O.

Both symmetrical cells were galvanostatically cycled at an areal capacity of 1.5 mAh/cm² and at a current density of 1.0 mA/cm² and 2.0 mA/cm². The cut-off voltage was +2 V. The cycling was performed at 25° C.

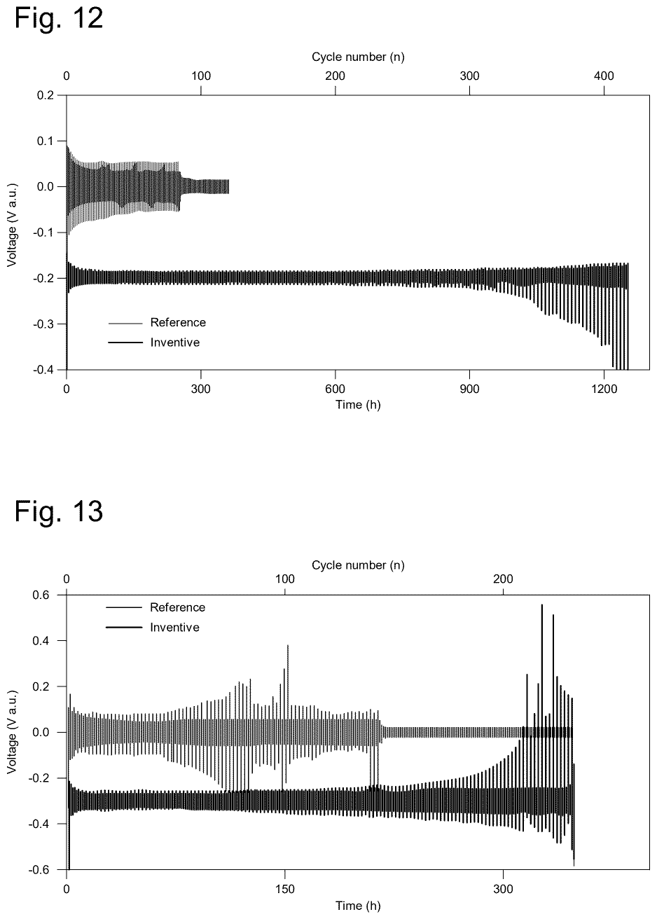

FIGS. 12 and 13 show the voltage profile for the inventive symmetrical cell and the reference symmetrical cell in function of time/the number of charging/discharging cycles for the 1.0 mA/cm² current density and the 2.0 mA/cm² current density, respectively. It is clear that for both current densities, the inventive symmetrical cell shows a stable cycling behaviour at a lower overpotential value for a significantly longer duration, i.e. a significantly higher number of charging/discharging cycles.

At a current density of 1.0 mA/cm² and the areal capacity of 1.5 mAh/cm² (FIG. 12), the inventive cell had an overpotential of only 12.4 mV at 200 hours cycling and remained stable for 1200 hours (400 cycles), while the reference cell had a hysteresis of 27.9 mV at 200 hours cycling, and was stable for only 278 hours (93 cycles). Further, the overpotential of the reference cells was higher than the overpotential of the inventive cell, which indicates a larger electrolyte degradation and accumulation of dead lithium (i.e. inactive resistive) lithium, which reduce the effectiveness of the lithium ion transport. More particularly, the inventive cells showed almost no overpotential development up to 900 hours cycling, thereby confirming the effectiveness of the Li₂O/LiOH passivation layer in the lithium ion transport and the reduction of dendrite formation.

At a current density of 2.0 mA/cm² and the areal capacity of 1.5 mAh/cm² (FIG. 13), the inventive cell had a hysteresis of only 24.1 mV at 100 hours cycling and remained stable for more than 300 hours (200 cycles), while the reference cell had a hysteresis of 52.1 mV mV at 100 hours cycling, and showed already unstable cycling behaviour after 100 hours (less than 100 cycles).

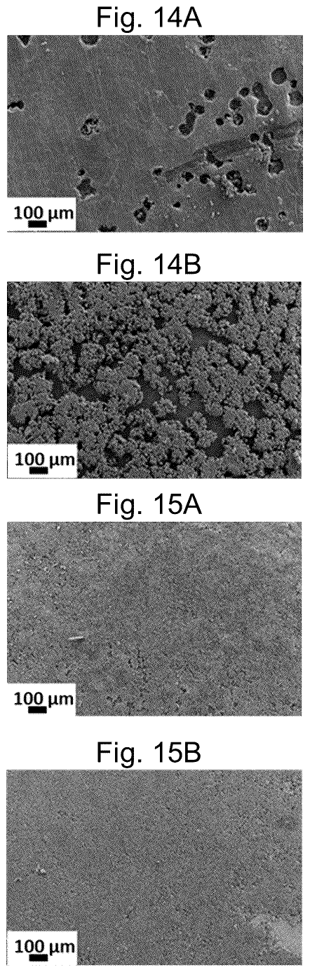

FIG. 14A and FIG. 14B show the SEM-images of the surface of the reference anode after 20 cycles of discharging (lithium stripping) and charging (lithium plating), respectively. From FIG. 14A it is clear that large pinholes have been formed after repeated lithium stripping, leading to irregular lithium plating (FIG. 14B).

FIG. 15A and FIG. 15B show the SEM-images of the surface of the inventive anode with the Li₂O/LiOH passivation layer after 20 cycles of discharging (lithium stripping) and charging (lithium plating), respectively. A much denser plated lithium is observed on the inventive anode compared to the reference anode (FIG. 15A vs. FIG. 14A). It supports the importance of the Li₂O/LiOH layer to improve the plated lithium density on the anode and limit the formation of mossy dead lithium. This leads to a much more regular lithium plating, when compared to the reference anode (FIG. 15B vs. FIG. 14B).

### Example 5

The same inventive and reference anodes of Example 4, i.e. again without a 90 nm LiF layer on top of the passivation layer were now used to assemble an inventive and a reference full battery cell, respectively. The battery cell assembly was again performed in the argon-filled glovebox of Example 4. As cathode for both battery cells, 13 mm diameter LFP electrode (17.5 mg/cm²) was used. The cathode was punched out and dried overnight at 120° C. in vacuum in order to remove any remaining water, prior to being transferred into the argon-filled glovebox. The electrolyte and separator used were the same as in Example 4. The battery cells were closed with a torque wrench like in Example 4, by providing the same stack pressure.

Both battery cells were galvanostatically cycled between 2.5 V and 4 V after two formation cycles at C/10 (17 mA/g) and then at a capacity of 1.5 mAh/cm² and at a current density of 1.0 mA/cm². The cycling was performed at 25° C.

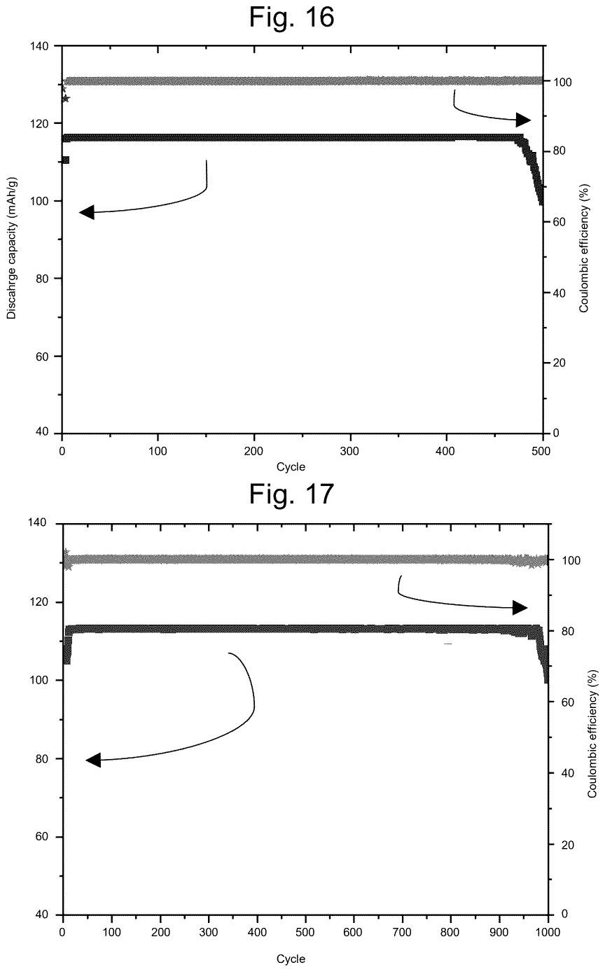

FIG. 16 and FIG. 17 show the discharge capacity and the Coulombic efficiency of the reference battery cell and the inventive battery cell, respectively, in function of the number of charging/discharging cycles. From FIG. 17 it is clear that the inventive battery cell delivers a stable capacity for more than 900 cycles. The reference battery cell, however, is only stable up to maximum 500 cycles, with a rapid decrease in performance with each further cycle (FIG. 16).

### Example 6

Six identical pouch cells were prepared using the anode of Example 2 having a passivation layer obtained by 25 min N₂ assisted RF sputtering, and a 90 nm LiF layer on top of the passivation layer. The pouch cells were assembled inside a dry room with dewpoint between −55° C. and −64° C. The anodes had a surface area of 7.56 cm². A LiFePO₄ (LFP) cathode (load 13 mg/cm², cell capacity 14 mAh) with surface area of 6.40 cm² was used. The electrodes were separated with a 16 μm Teijin separator. 60 μL of ether-based electrolyte containing 2M LiFSI salt was used in the pouch cells.

The six as-assembled pouch cells were cycled under ambient condition and without applied external pressure using a NEWARE Battery Testing System. 15 formation cycles were performed between C/10 (current of approx. 1.0 mA and current density between 0.10 and 0.20 mA/cm²) and C/3 (current of 4 mA and current density of 1 mA/cm². Then, the pouch cells were galvanostatically cycled between 2.2 V and 3.8 V at C/3 charge (current of 4 mA, current density of 1 mA/cm²) and 1C discharge (current of 10 mA, current density of 2 mA/cm²) cycling protocols.

30 identical reference pouch cells were also tested in the same conditions and using the same cycling protocols. These reference pouch cells comprised as anode the anode active substrate of Example 2, but without any passivation layer and without any lithium metal anode protective layer. The cathode, separator and electrolyte were the same as for the 6 inventive pouch cells.

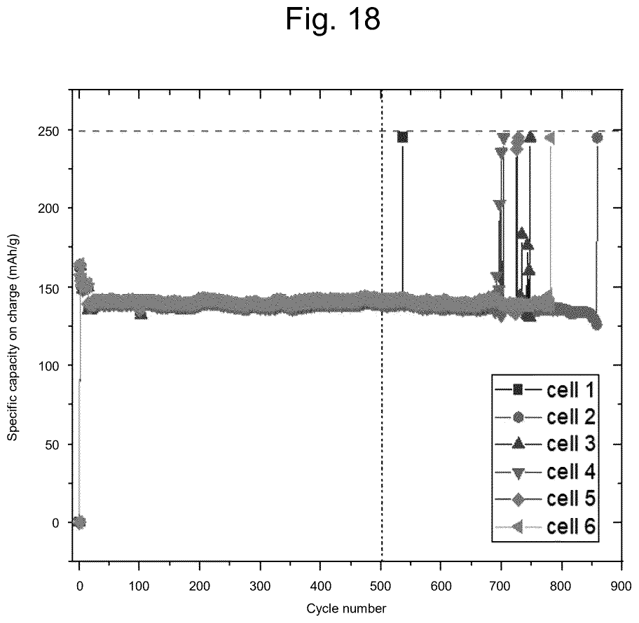

FIG. 18 shows the discharge capacity of the six identical inventive pouch cells in function of the number of charging/discharging cycles. The vertical dotted line represents the average cycling performance of the 30 identical reference pouch cells. It is clear that the inventive pouch cells, having a passivation layer and a LiF lithium metal anode protective layer, deliver a stable capacity for more than 550 cycles, the average number of cycles being around 700. Further, the number of cycles during which these six cells are stable is quite similar, which indicates that the inventive method of producing the anode is repeatable and reproducible. However, the reference pouch cells deliver a stable capacity for only, on average, 500 cycles. Consequently, the inventive pouch cells clearly outperform the reference pouch cells.

### NOMENCLATURE

1. Lithium metal anode
2. Anode active substrate
3. First lithium metal anode protective layer
4. Surface of anode active substrate
5. Second lithium metal anode protective layer
6. Anode current collector
7. Layer comprising lithium metal
8. Native layer of impurities
9. Passivation layer
10. Lithium metal anode
11. Lithium metal anode
12. Lithium metal anode
13. Lithium metal anode
20. Battery cell with reference lithium metal anode
21. Battery cell with inventive lithium metal anode
22. Battery cell with inventive lithium metal anode

1. A lithium metal anode (1, 10, 11, 12, 13, 14) for a battery, comprising an anode active substrate (2) comprising lithium metal, and a first lithium metal anode protective layer (3) provided on a surface (4) of the anode active substrate (2), wherein the anode (1, 10, 11, 12, 13) further comprises one or more of lithium carbonate (Li₂CO₃), lithium oxide (Li₂O) and lithium hydroxide (LiOH), characterized in that the first lithium metal anode protective layer (3) comprises a first halide of lithium.

2. The lithium metal anode (11, 13) according to claim 1, further comprising a second lithium metal anode protective layer (5) provided on the first lithium metal anode protective layer (3), wherein the second lithium metal anode protective layer (5) comprises a second halide of lithium.

3. The lithium metal anode (1, 10, 11, 12, 13, 14) according to claim 1, wherein the first halide of lithium and the optional second halide of lithium, individually, is (are) lithium iodide (LiI) or lithium fluoride (LiF).

4. The lithium metal anode (1, 10, 11, 12, 13, 14) according to claim 3, wherein the first lithium metal anode protective layer (3) and/or the optional second lithium metal anode protective layer (5) comprises LiI and has a thickness between 5 nm and 800 nm.

5. The lithium metal anode (1, 10, 11, 12, 13, 14) according to claim 3, wherein the first lithium metal anode protective layer (3) and/or the optional second lithium metal anode protective layer (5) comprises LiF and has a thickness between 50 nm and 200 nm.

6. The lithium metal anode (11, 13) according to claim 2, comprising a second lithium metal anode protective layer (5), wherein the first halide of lithium of the first lithium metal anode protective layer (3) is LiI, and the second halide of lithium of the second lithium metal anode protective layer (5) is LiF.

7. The lithium metal anode (10, 11) according to claim 1, wherein the anode active substrate (2) comprises a layer comprising lithium metal (7) provided on a surface of an anode current collector (6), and further comprises a native layer of impurities (8) on the layer comprising lithium metal (7), wherein the native layer of impurities (8) comprises the one or more of Li₂CO₃, Li₂O and LiOH.

8. The lithium metal anode (12, 13, 14) according to claim 1, further comprising a passivation layer (9) comprising the one or more of Li₂CO₃, Li₂O and LiOH, wherein the passivation layer (9) is provided between the anode active substrate (2) and the first lithium metal anode protective layer (3), and wherein the surface of the passivation layer (9) adjacent to the first lithium metal anode protective layer (3) comprises at least 80% of one or more of Li₂O, LiOH and LiₓPO_{y}N_{z} (LIPON), wherein x, y and z, individually, are higher than 0, as measured by quantification X-ray photoelectron spectroscopy (XPS).

9. The lithium metal anode (12, 13, 14) according to claim 8, wherein the surface of the passivation layer (9) adjacent to the first lithium metal anode protective layer (3) comprises at most 5%, preferably at most 3% of Li₂CO₃.

10. The lithium metal anode (12, 13, 14) according to claim 8, wherein the passivation layer (9) has a thickness between 100 and 1000 nm.

11. The lithium metal anode (14) according to claim 8, wherein the surface of the passivation layer (9) adjacent to the first lithium metal anode protective layer (3) comprises Li₂CO₃, Li₂O and LiOH, as measured by the total electron yield (TEY) signal of X-ray absorption Spectroscopy (XAS), and further comprises Li₂O and/or LiOH in the bulk portion (16) of the passivation layer (9), as measured by the total fluorescence yield (TFY) signal of XAS.

12. A lithium-ion battery comprising the lithium metal anode (1, 10, 11, 12, 13, 14) according to claim 1.

13. The lithium-ion battery according to claim 12, being a secondary battery.

14. A method of producing a lithium metal anode (1, 10, 11, 12, 13, 14) comprising an anode active substrate (2) comprising lithium metal, and a first lithium metal anode protective layer (3) comprising a first halide of lithium and provided on a surface (4) of the anode active substrate (2), the method comprising depositing a first lithium metal anode protective layer (3) on a surface (4) of an anode active substrate (2) comprising lithium metal by means of thermal evaporation of a first coating composition, thereby obtaining the anode (1, 10, 11, 12, 13, 14), characterized in that the first coating composition comprises a first halide of lithium.

15. The method according to claim 14, further comprising depositing a second lithium metal anode protective layer (5) on first lithium metal anode protective layer (3) by means of thermal evaporation of a second coating composition comprising a second halide of lithium.

16. The method according to claim 14, wherein the first coating composition and the optional second coating composition, individually, has (have) a temperature between 200° C. and 1000° C. during the respective thermal evaporation thereof.

17. The method according to claim 14, wherein the first halide of lithium and the optional second halide of lithium, individually, is (are) lithium iodide (LiI) or lithium fluoride (LiF).

18. The method according to claim 17, wherein the first halide of lithium and/or the optional second halide of lithium is (are) LiI, and wherein the respective coating composition(s) comprising LiI has (have) a temperature between 250° C. and 400° C. during the respective thermal evaporation thereof.

19. The method according to claim 17, wherein the first halide of lithium and/or, the optional second halide of lithium is (are) LiF, and wherein the respective coating composition(s) comprising LiF has (have) a temperature between 500° C. and 900° C.

20. The method according to claim 14, wherein the thermal evaporation of the first coating composition and/or the optional second coating composition, individually, is conducted between 1 and 50 times, preferably between 10 and 20 times, thereby obtaining the first lithium metal anode protective layer (3) and/or the optional second lithium metal anode protective layer (5), respectively.

21. The method according to claim 14, further comprising a step of gas assisted radio frequency (RF) sputtering using a target substrate comprising Li3PO4, prior to deposition of the first lithium metal anode protective layer (3).

22. The method according to claim 21, wherein the gas is nitrogen, argon, helium or a combination of two or more thereof.

23. The method according to claim 21, wherein the target substrate comprising Li₃PO₄ has a temperature between 10° C. and 50° C., preferably between 15° C. and 35° C. during the gas assisted RF sputtering.

24. The method according to claim 21, wherein the gas assisted RF sputtering has a duration between 5 minutes and 2.5 hours.
